(19) United States
(12) Patent Application Publication
(10) Pub. No.: US 2014/0060780 A1
(43) Pub. Date: Mar. 6, 2014

(54) FLAT HEAT PIPE AND FABRICATION METHOD THEREOF

(71) Applicant: Electronics and Telecommunications Research Institute, Daejeon (KR)

(72) Inventor: Seok Hwan MOON, Daejeon (KR)

(21) Appl. No.: 13/909,172

(22) Filed: Jun. 4, 2013

(30) Foreign Application Priority Data
Aug. 29, 2012 (KR) 10-2012-0094704

(51) Int. Cl. H05K 7/20; B23P 15/26

(52) U.S. Cl. CPC H05K 7/20336; B23P 15/26
USPC 165/104.21; 29/890.032

(57) ABSTRACT

The present disclosure relates to a flat heat pipe in which a plurality of minute wires is inserted and a fabrication method thereof. A flat heat pipe according to an exemplary embodiment of the present disclosure includes a through hole which is formed in a flat panel shaped body in a longitudinal direction one or more grooves which are formed above an inner wall of the through hole, and a plurality of wires which is inserted below the inner wall of the through hole in the longitudinal direction.

### CROSS-REFERENCE TO RELATED APPLICATIONS

This application is based on and claims priority from Korean Patent Application No. 10-2012-0094704 filed on 2012, Aug., 29 with the Korean Intellectual Property Office, the disclosure of which is incorporated herein in its entirety by reference.

### TECHNICAL FIELD

The present disclosure relates to a flat heat pipe and a fabrication method thereof having excellent capillary force, and more particularly, to a flat heat pipe which has a flat panel shape and includes a predetermined through hole formed therein, one or more grooves having an edge formed above the through hole, and a plurality of wires inserted below the through hole, and a fabrication method thereof.

### BACKGROUND

Generally, a chip and a system which are packaged in electronic equipment become highly integrated and small-sized in accordance with the development of a technology of manufacturing a semiconductor. In accordance with this trend, a heat generating density of components included in the electronic equipment is significantly increased, and thus a cooling method to efficiently dissipate heat is required. Specifically, since small thickness is also achieved together with the down-sizing of the electronic equipment, a size of a cooling device to be applied needs to be reduced and thus the thickness thereof needs to be reduced.

Examples of the cooling device of the related art, which is applicable to small-sized electronic equipment, include a heat sink, a fan, and a small heat pipe.

Because heat sinks may be fabricated freely in terms of size and width, heat sinks have been widely used as a basic cooling means However, when a very small size is required, the heat dissipation rate becomes relatively less due to the reduction in the heat dissipating area.

With a fan, there is a limit to how much the size thereof can be reduced, and there is the problem in which the reliability thereof is relatively reduced.

A small-sized heat pipe has a circular cross-sectional structure having a diameter of 3 mm or larger and may be used to be pressed so as to be suitable for a thin film structure. However, because a miniature heat pipe with such a circular cross sectional diameter is designed with an initially circular cross section, when the heat pipe is compressed to fit electronic equipment with a miniature and thin film structure, heat dissipating performance is greatly reduced by a change in wick structure.

Therefore, development of a flat heat pipe having a flat panel shape and high capillary force, which is suitable for electronic equipment having a small and thin film structure, is required.

### SUMMARY

The present disclosure has been made in an effort to provide a flat heat pipe that secures a vapor flow space in a flat panel shaped body and facilitates flow of a working fluid to improve the heat transfer property, and a fabrication method thereof.

An exemplary embodiment of the present disclosure provides a flat heat pipe including a through hole which is formed in a flat panel shaped body in a longitudinal direction, one or more grooves which are formed above an inner wall of the through hole, and a plurality of wires which is inserted below the inner wall of the through hole in the longitudinal direction.

The plurality of wires may be provided so as to be one layer or overlaid by plural layers.

The inside of the through hole may be maintained to be a vacuum status.

The one or more grooves may be formed to be a polygonal shape having an edge.

The flat heat pipe may further include one or more separation films which separate the through hole into a plurality of sub through holes.

Another exemplary embodiment of the present disclosure provides a fabrication method of a flat heat pipe including forming a flat panel shaped body having a through hole formed therein in a longitudinal direction using an extrusion process, and inserting a plurality of wires below an inner wall of the through hole.

In the forming of a flat panel shaped body, one or more grooves may be formed above the inner wall of the through hole.

In the forming of a flat panel shaped body, a separation film which separates the through hole into a plurality of sub through holes may be formed.

The plurality of wires may be inserted so as to be one layer or overlaid by plural layers.

After the inserting of the plurality of wires, the method may further include fixing the plurality of inserted wires to the body by pressing one side or both sides of the body.

After the forming of the flat panel shaped body, the method may further include filling a working fluid inside the through hole and sealing the inside of the through hole.

According to the exemplary embodiments of the present disclosure, a plurality of minute wires is inserted at the bottom of the inside of the through hole in the flat panel shaped body so that a liquid working fluid flows by a capillary force generated at a contacted portion between the wires to further improve a heat transfer property of the flat heat pipe.

According to the exemplary embodiments of the present disclosure, one or more grooves are formed on a top surface of the inside of the through hole in the flat panel shaped body to efficiently disperse liquid droplets generated by condensation of steam over an insulator section and a condenser section except for an evaporator section.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a partially exploded perspective view illustrating a flat heat pipe according to a first exemplary embodiment of the present disclosure.

FIG. 2 is a partially exploded perspective view illustrating a flat heat pipe according to a second exemplary embodiment of the present disclosure.

FIG. 3 is a partially exploded perspective view illustrating a flat heat pipe according to a third embodiment of the present disclosure.

### DETAILED DESCRIPTION

In the following detailed description, reference is made to the accompanying drawing, which form a part hereof. Hereinafter, a configuration of the present disclosure and an operation and advantages in accordance with the configuration will be apparent from the following detailed description. Like reference numerals designate like elements throughout the specification. A detailed explanation of known related functions and constitutions may be omitted when it is determined that the detailed explanation obscures the subject matter of the present disclosure.

A heat pipe is formed by injecting a working fluid in a sealed container and then evacuating the working fluid and has a structure in which if an end of the heat pipe is heated, the working fluid therein is vaporized to be moved to the other end by a pressure difference and releases heat to the surroundings and then returns to a heating unit through a condensation process. In order to cause capillary force, a wick may be inserted in the heat pipe.

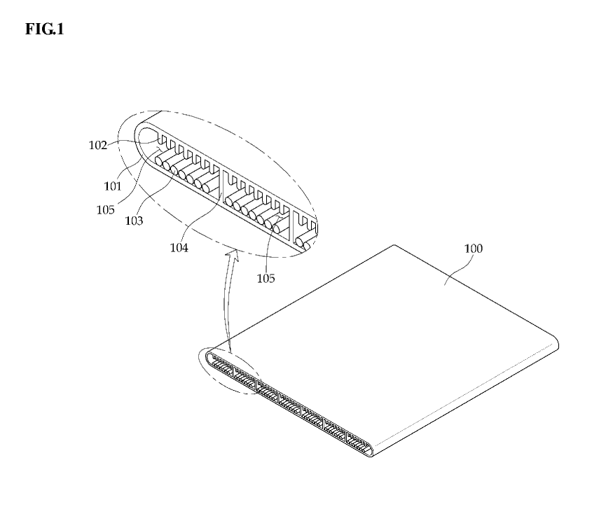

FIG. 1 is a configuration view of a flat heat pipe according to an exemplary embodiment of the present disclosure.

Referring to FIG. 1, The flat heat pipe according to the first exemplary embodiment of the present disclosure includes a through hole 101 formed in a flat panel shaped body 100 in a longitudinal direction, one or more grooves 102 configured to be formed above an inner wall of the through hole 101, and a plurality of wires 103 which is inserted below the inner wall of the through hole 101 in the longitudinal direction. The flat heat pipe may further include one or more separation films 104 which separates the through hole 101 into a plurality of sub through holes 105.

The body 100 is manufactured to be a flat pipe shaped metal plate by one extrusion process.

The through hole 101 is formed in the body 100 so that a working fluid injected from the outside flows.

On a bottom surface at the inner side of the through hole 101, as many as possible minute wires 103 are inserted in the same longitudinal direction as the through hole 101 to cover the bottom surface. A capillary force is generated by the edges of the contact line of the minute wires 103 so that the liquefied working fluid flows.

In the meantime, on a top surface of the inner side of the through hole 101, a plurality of U shaped grooves 102, which extends in the same longitudinal direction as the through hole 101, is formed. Liquid droplets generated by the condensation of the steam are dispersed by the formed grooves 102 on the inner wall of the body except for a portion to which heat is input from one side of the flat heat pipe. The capillary force is generated by the edge of the U shaped groove 102 so that the liquefied working fluid flows.

In the flat heat pipe according to the first exemplary embodiment of the present disclosure, the liquefied working fluid may flow by the capillary force generated in the plurality of minute wires 103 and the edge of the U shaped groove 102 without using a wick of the related art which serves as a passage to allow the liquefied working fluid to flow (return) from a condenser section to an evaporator section. In other words, the edges of the plurality of grooves 102 may serve as the wick of the related art.

The flat heat pipe according to the first exemplary embodiment of the present disclosure discharges the heat therein to the outside as phase change occurs between the liquid and steam by the liquefied working fluid injected while the inside of the flat heat pipe is maintained in a vacuum status.

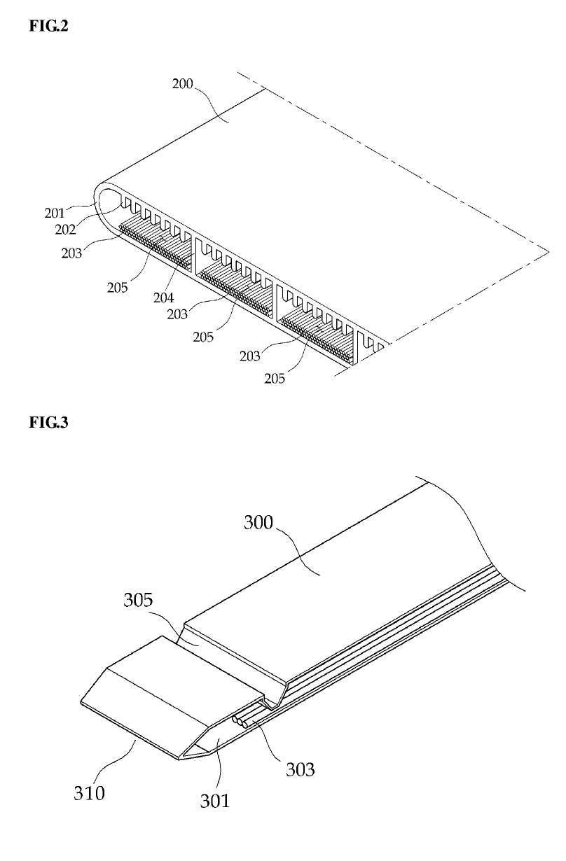

FIG. 2 is a configuration view of a flat heat pipe according to a second exemplary embodiment of the present disclosure.

Referring to FIG. 2, the flat heat pipe according to the second exemplary embodiment of the present disclosure includes a through hole 201 formed in a flat panel shaped body 200 in a longitudinal direction, one or more grooves 202 configured to be formed above an inner wall of the through hole 201, and a plurality of wires 203 which is inserted below the inner wall of the through hole 201 in the longitudinal direction to be inserted as one or more layers. The flat heat pipe may further include one or more separation films 204 which separates the through hole 201 into a plurality of sub through holes 205.

The plurality of wires 203 of the second exemplary embodiment has more minute wires 203 than the wires 103 of the first exemplary embodiment. The capillary force is generated by the edges formed when the minute wires 203 are in contact with each other so that the liquefied working fluid flows.

In the meantime, on a top surface of the inner side of the through hole 201, a plurality of U shaped grooves 202, which extends in the same longitudinal direction as the through hole 201, is formed. Liquid droplets generated by the condensation of the steam are dispersed by the formed grooves 202 on the inner wall of the body except for a portion to which heat is input from one side of the heat pipe. The capillary force is generated by the edge of the U shaped groove 202 so that the liquefied working fluid flows.

A plurality of fluid channels is formed in the through hole by the separation film 204 which separates the through hole into a plurality of sub through holes 205.

In the flat heat pipe according to the second exemplary embodiment of the present disclosure, the liquefied working fluid may flow by the capillary force generated in the plurality of minute wires 203 and the edge of the U shaped groove 203 without using a wick of the related art which serves as a passage to allow the liquefied working fluid to flow (return) from a condenser section to an evaporator section. In other words, the edges of the plurality of grooves 202 may serve as the wick of the related art. Features and effects of the other configurations are the same as the description with reference to FIG. 1.

Next, a fabrication method of a flat heat pipe will be described.

The fabrication method of a flat heat pipe includes forming a body using an extrusion process, and inserting a plurality of minute wires below an inner wall of a through hole.

A body 300 having a flat panel shape includes a through hole 301 formed in a longitudinal direction, one or more grooves 302 configured to be formed above the inner wall of the through hole 301, and a separation film 304 which separates the through hole 301 into sub through holes 305.

That is, the body 300, the through hole 301, the grooves 302, and the separation film 304 may be formed by one extrusion process. If not necessary, the separation film 304 may not be formed.

The minute wires are inserted so as to be overlaid by one layer or plural layers.

After inserting the wires, as illustrated in FIG. 3, a working fluid is filled in the through hole 301 and the inside of the through hole is sealed (310) (a finishing step).

In order to fix the plurality of inserted wires 303 to the body 300, a portion, which is separated from an edge or both edges of the body by a predetermined distance, is pressed (305) so that the plurality of inserted wires 303 is fixed to the body 300 (pressing step).

The finishing step and the pressing step may separately proceed and the order of the steps may be changed if necessary.

As described above, the flat heat pipe according to the first to third embodiments of the present disclosure has a minute thickness of approximately 2 mm and has an excellent heat dissipating property and a heat transfer property so as to be efficiently used as a cooling means for small and thin film electronic equipment.

A technical spirit of the present disclosure has been specifically described with reference to the preferred embodiment but it is noted that the exemplary embodiment is for illustrative purpose only and does not limit the scope of the present disclosure. It is understood by those skilled in the art that various embodiments may be allowed within a scope of the technical spirit of the present disclosure.

For example, the grooves 103 and 203 which are applied to the first and second embodiments of the present disclosure may be formed as a V shape or a polygonal shape having at least one edge other than the U shape.

From the foregoing, it will be appreciated that various embodiments of the present disclosure have been described herein for purposes of illustration, and that various modifications may be made by those skilled in the art without departing from the scope and spirit of the present disclosure. Accordingly, the various embodiments disclosed herein are not intended to be limiting. The scope of the present disclosure should be construed by the appended claims and all technologies within the equivalent scope to that of the present disclosure should be construed as being included in the scope of the present disclosure.

What is claimed is:

1. A flat heat pipe, comprising:
a through hole which is formed in a flat panel shaped body in a longitudinal direction;
one or more grooves which are formed above an inner wall of the through hole; and
a plurality of wires which is inserted below the inner wall of the through hole in the longitudinal direction.

2. The flat heat pipe of claim 1, wherein the plurality of wires is inserted so as to be overlaid by one layer or plural layers.

3. The flat heat pipe of claim 1, wherein the inside of the through hole is maintained in a vacuum state.

4. The flat heat pipe of claim 1, wherein the one or more grooves are formed to be a polygonal shape having an edge.

5. The flat heat pipe of claim 1, further comprising:
one or more separation films which separate the through hole into a plurality of sub through holes.

6. A fabrication method of a flat heat pipe, comprising:
forming a flat panel shaped body having a through hole formed therein in a longitudinal direction using an extrusion process; and
inserting a plurality of wires below an inner wall of the through hole.

7. The fabrication method of claim 6, wherein in the forming of the flat panel shaped body, one or more grooves are formed above the inner wall of the through hole.

8. The fabrication method of claim 7, wherein in the forming of the flat panel shaped body, a separation film which separates the through hole into a plurality of sub through holes is formed.

9. The fabrication method of claim 6, wherein the plurality of wires is inserted so as to be one layer or overlaid by plural layers.

10. The fabrication method of claim 6, further comprising:
after the inserting of the plurality of wires, fixing the plurality of inserted wires to the body by pressing one or side or both sides of the body.

11. The fabrication method of claim 6, further comprising:
after the forming of the flat panel shaped body, filling an operating fluid inside the through hole and sealing the inside of the through hole.
